(19) United States
(12) Patent Application Publication
(10) Pub. No.: US 2009/0213893 A1
(43) Pub. Date: Aug. 27, 2009

(54) END PUMPING VERTICAL EXTERNAL CAVITY SURFACE EMITTING LASER

(75) Inventors: Ki-sung KIM, Hwaseong-si (KR); Taek Kim, Seongnam-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/417,174

(22) Filed: Apr. 2, 2009

Related U.S. Application Data
(63) Continuation of application No. 11/446,153, filed on Jun. 5, 2006.

(30) Foreign Application Priority Data
Sep. 6, 2005 (KR) 10-2005-0082623

(51) Int. Cl. H01S 5/125; H01S 5/183; H01S 3/091

(52) U.S. Cl. 372/50.11; 372/50.124; 372/71

(57) ABSTRACT

A vertical external cavity surface emitting laser (VECSEL) is provided, in which the incident loss of a pumping beam is reduced. The VECSEL device comprising: a transparent substrate; an optical pump radiating a pumping beam onto a first surface of the transparent substrate; a first anti-reflection coating (ARC) layer formed of a first light-transmitting insulating material on a second surface of the transparent substrate to reduce loss of the pumping beam; a distributed Bragg reflector (DBR) layer formed on the first ARC layer; a periodic gain layer formed on the DBR layer; and an external cavity mirror facing the periodic gain layer.

### CROSS-REFERENCE TO RELATED PATENT APPLICATION

This application is a continuation of U.S. application Ser. No. 11/446,153 filed on Jun. 5, 2006, which claims the benefit of Korean Patent Application No. 10-2005-0082623, filed on Sep. 6, 2005, in the Korean Intellectual Property Office, the disclosure of which are incorporated herein in their entirety by reference.

### BACKGROUND OF THE DISCLOSURE

1. Field of the Disclosure

The present disclosure relates to a vertical external cavity surface emitting laser (VECSEL) device, and more particularly, to a VECSEL device with an improved structure in which incident loss of a pumping beam when driving is reduced.

2. Description of the Related Art

A vertical cavity surface emitting laser (VCSEL) emits a very narrow spectrum during single longitudinal operation and has a high coupling efficiency since its projection angle is small. Other apparatus can be readily integrated with a VCSEL due to the surface emitting structure of the VCSEL. Thus, VCSELs can be used for pumping laser diodes (LDs).

However, the width of the emission region of the VCSEL must be less than 10 μm for a general horizontal operation of the VCSEL. Even then, since the VCSEL is easily changed into a multiple mode due to a thermal lens effect according to an increased light output, the maximum output generally is not greater than 5 mW during a single longitudinal operation.

A vertical external cavity surface emitting laser (VECSEL) device has been suggested to enhance the above-described advantages of the VCSEL and to realize high output. In the VECSEL, a gain region can be increased by replacing an upper distributed Bragg reflector (DBR) layer with an external mirror, and an output of 100 mW or more can be obtained. Recently, to make up for the disadvantage that it is difficult to obtain sufficient gain in a surface emitting laser due to the small gain volume compared to an edge emitting laser, a VECSEL device with a periodic gain structure in which quantum wells are periodically placed has been developed. Also, as it is limited to uniformly inject carriers to a large area by electric pumping, a VECSEL device has been developed in which a large area is pumped uniformly with carriers by optical pumping in order to obtain high output.

FIG. 1 is a schematic cross-sectional view of a conventional end pumping VECSEL. FIG. 2 is a graph of the reflectivity of the DBR layer according to the wavelength of the pumping beams in the VECSEL of FIG. 1.

Referring to FIG. 1, the conventional VECSEL includes a transparent substrate 10, and a DBR reflector layer 16 and a periodic gain layer 18 stacked sequentially on the transparent substrate 10, an optical pump 20 radiating a pumping beam to the transparent substrate 10, and an external cavity mirror 30 facing the periodic gain layer 18.

In the conventional VECSEL device, more than 30% of the pumping beam incident on an interface of the DBR layer 16 is reflected and the pumping efficiency given by the fraction of the pumping beam incident on the gain region is relatively low such as 70%. Referring to FIG. 2, 30% of a pumping beam with a wavelength of 808 nm is reflected at the interface of the DBR layer 16. As described, lasing efficiency may be decreased since the incident pumping beam reflection at the interface of the DBR layer 16 decreases the gain efficiency. Accordingly, a VECSEL device with a structure in which incidence loss of a pumping beam is reduced to increase pumping beam efficiency must be developed.

### SUMMARY OF THE DISCLOSURE

The present invention may provide a vertical external cavity surface emitting laser (VECSEL) device with an improved structure in which the loss of a pumping beam when driving is reduced.

According to an aspect of the present invention, there may be provided a VECSEL device comprising: a transparent substrate; an optical pump radiating a pumping beam onto a first surface of the transparent substrate; a first anti-reflection coating (ARC) layer formed of a first light-transmitting insulating material on a second surface of the transparent substrate to reduce incident loss of the pumping beam; a distributed Bragg reflector (DBR) layer formed on the first ARC layer; a periodic gain layer formed on the DBR layer; and an external cavity mirror facing the periodic gain layer.

The first light-transmitting insulating material may have a different refraction index than the DBR layer and the first ARC layer may have a single-layer or a double-layer structure. The first ARC layer may have a thickness of ¼ of the wavelength of the pumping beam. The wavelength of the pumping beam may be in the range from approximately 700 nm to approximately 900 nm.

The first ARC layer may have the double-layer structure comprising a first material layer having a refractive index n1 and a second material layer having a refractive index n₂ (n₂≠n₁). The first ARC layer may have a thickness such that the reflectivity p of the interface between the DBR layer and the first ARC layer is 5% or less with respect to the pumping beam.

The reflectivity p of the interface between the DBR layer and the ARC layer may satisfy

$$ρ = \frac{{η}_{0} - Y}{{η}_{0} + Y} = \frac{{η}_{0} - \frac{C}{B}}{{η}_{0} + \frac{C}{B}}$$

where η₀ is the modified optical admittance of the incident medium, B is the magnitude of an electric field at the interface between the ARC layer and the DBR layer, C is the magnitude of a magnetic field at the interface between the ARC layer and the DBR layer, and Y is the optical admittance of the DBR layer.

The above described B and C may satisfy

$$[ \begin{matrix}B \\ C\end{matrix} ] = [ \begin{matrix}cos {δ}_{1} & \frac{( i sin {δ}_{1} )}{{η}_{1}} \\ i {η}_{1} sin {δ}_{1} & cos {δ}_{1}\end{matrix} ] [ \begin{matrix}cos {δ}_{2} & \frac{( i sin {δ}_{2} )}{{η}_{2}} \\ i {η}_{2} sin {δ}_{2} & cos {δ}_{2}\end{matrix} ] [ \begin{matrix}1 \\ {Y}_{k} ( λ )\end{matrix} ]$$

$${δ}_{i} = ( 2 π / λ ) {n}_{i} {d}_{i} cos {θ}_{i} ( i = 1 , 2 )$$

where δ is the optical phase thickness of the DBR layer or ARC layer, Yₖ is the optical admittance of the DBR layer, η₁ and η₂ are respectively the modified optical admittances of the first and second material layers, θᵢ is the incidence angle of the pumping beam, λ is the wavelength of the pumping beam, d₁ and d₂ are respectively the thicknesses of the first and second material layers, and n₁ and n₂ are respectively the refraction indexes of the first and second material layers.

The first ARC layer may include TiO₂ layers having a thickness of 161 nm and SiO₂ layers having a thickness of 202 nm stacked sequentially on the second surface of the transparent substrate. The first ARC layer may include GaAs layers having a thickness of 100 nm and Al_{0.8}GaAs layers having a thickness of 130 nm stacked sequentially on the second surface of the transparent substrate.

The DBR layer may include AlAs layers and AlGaAs layers alternately stacked. The transparent substrate may be a substrate selected from the group consisting of a SiC substrate, a diamond substrate, an AlN substrate, and a BeO substrate.

A second ARC layer made of a second light transmitting insulating material on the first surface of the transparent substrate to reduce the incident loss of the pumping beam may be further included. The second light transmitting insulating material may be SiO₂ or TiO₂. The second ARC layer may have a thickness of ¼ of the wavelength of the pumping beam.

According to the present invention, the incident loss of the pumping beam during driving of the VECSEL device can be reduced and the pumping efficiency can be increased.

### BRIEF DESCRIPTION OF THE DRAWINGS

The above and other features and advantages of the present invention will be described in detailed exemplary embodiments thereof with reference to the attached drawings in which:

FIG. 1 is a schematic cross-sectional view of a conventional vertical external cavity surface emitting laser (VECSEL) device using end pumping;

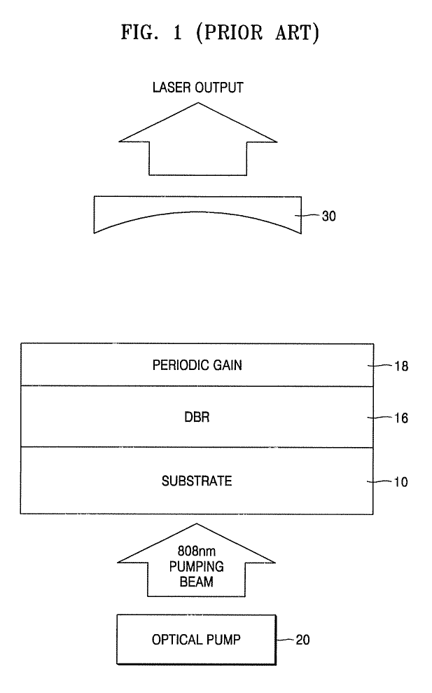

FIG. 2 is a graph of the reflectivity of a distributed Bragg reflector (DBR) layer according to the wavelength of a pumping beam in the VECSEL device of FIG. 1;

FIG. 3 is a schematic cross-sectional view of a VECSEL device according to an embodiment of the present invention;

FIG. 4 is a graph of the reflectivity of a DBR layer according to the wavelength of a pumping beam in the VECSEL device of FIG. 3;

FIG. 5 is a schematic cross-sectional view of a VECSEL device according to another embodiment of the present invention; and

FIG. 6 is a graph of the reflectivity of a DBR layer according to the wavelength of a pumping beam in the VECSEL device of FIG. 5.

### DETAILED DESCRIPTION OF EXEMPLARY EMBODIMENTS

The present invention will now be described more fully with reference to the accompanying drawings, in which exemplary embodiments of the invention are shown. In the drawings, the thicknesses of layers and regions are exaggerated for clarity. Like reference numbers denote like elements throughout the drawings.

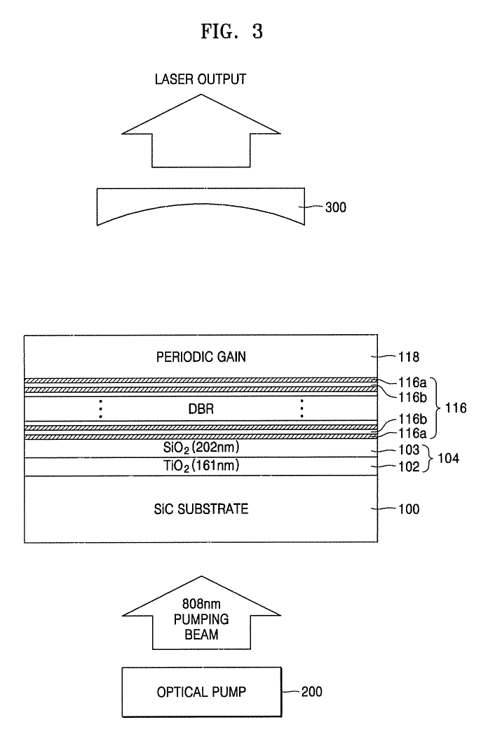

FIG. 3 is a schematic cross-sectional view of a VECSEL device according to an embodiment of the present invention. Referring to FIG. 3, the VECSEL device includes a transparent substrate 100, an optical pump 200 disposed below the transparent substrate 100 to radiate a pumping beam onto the transparent substrate 100, a first anti-reflection coating (ARC) layer 104, a distributed Bragg reflection (DBR) layer 116, and a periodic gain layer 118 sequentially stacked on the transparent substrate 100, and an external cavity mirror 300 facing the periodic gain layer 118. The transparent substrate 100 may be a substrate selected from the group consisting of a SiC substrate, a diamond substrate, an AlN substrate, and a BeO substrate. The structure and manufacturing processes for the DBR layer 116 and the periodic gain layer 118 are well known, and thus their description will be omitted. The wavelength of the pumping beam is from approximately 700 nm to approximately 900 nm.

The first ARC layer 104 is formed of a first light-transmitting insulating material in a single-layer structure or double-layer structure, thereby reducing the incident loss of the pumping beam on the incident surface of the DBR layer 116. The first light-transmitting insulating material may be any material which has a different refraction index than the DBR layer 116. The first light-transmitting insulating material may be TiO₂, SiO₂, GaAs, or Al_{0.8}GaAs. The first ARC layer 104 in a single-layer structure may have a thickness of ¼ of the wavelength of the pumping beam.

The first ARC layer 104 includes a first material layer 102 having a refraction index of n1 and a second material layer 103 having a refraction index of n₂ (n₂≠n₁). The thickness of the first ARC layer 104 is such that the reflectivity of the interface between the DBR layer 116 and the first ARC layer 104 is less than approximately 5%. The difference between n₁ and n₂ may be great with respect to the pumping beam.

The thicknesses d₁ and d₂ of the first material layer 102 and the second material layer 103 may be made to satisfy this condition based on Equations 1, 2, and 3. The reflectivity p of the interface between the DBR layer 116 and the first ARC layer 104 can be represented by Equation 1 below.

$$ρ = \frac{{η}_{0} - Y}{{η}_{0} + Y} = \frac{{η}_{0} - \frac{C}{B}}{{η}_{0} + \frac{C}{B}} \qquad Equation 1$$

where η0 is the modified optical admittance of the incident medium (η0=n0 cos θ0 for TE polarization and η0=n0/cos θ0 for TM polarization), n0 is the refractive index of the substrate, θ0 is the angle of incidence of the pumping beam on the substrate, B is the magnitude of the electric field at the interface, C is the magnitude of the magnetic field at the interface, and Y is the optical admittance of the DBR layer 116.

The B and C can be expressed as in Equation 2.

$$[ \begin{matrix}B \\ C\end{matrix} ] = [ \begin{matrix}cos {δ}_{1} & \frac{( i sin {δ}_{1} )}{{η}_{1}} \\ i {η}_{1} sin {δ}_{1} & cos {δ}_{1}\end{matrix} ] [ \begin{matrix}cos {δ}_{2} & \frac{( i sin {δ}_{2} )}{{η}_{2}} \\ i {η}_{2} sin {δ}_{2} & cos {δ}_{2}\end{matrix} ] [ \begin{matrix}1 \\ {Y}_{k} ( λ )\end{matrix} ] \\ {δ}_{i} ( 2 π / λ ) {n}_{i} {d}_{i} cos {θ}_{i} ( i = 1 , 2 ) \qquad Equation 2$$

where δ is the optical phase thickness of a layer, Yₖ is the optical admittance of the DBR layer 116, η₁ and η₂ are respectively the modified optical admittances of the first and second material layers 102 and 103, θᵢ is the incidence angle of the pumping beam, λ is the wavelength of the pumping beam, d₁ and d₂ are respectively the thicknesses of the first and second material layers 102 and 103, and n₁ and n₂ are respectively the refraction indexes of the first and second material layers 102 and 103.

In Equation 1 and Equation 2, the optical admittance of the DBR layer is defined as Y=Yₖ=Hₓ/E_{y} (TE polarized light) or Y=Yₖ=H_{y}/Eₓ (TM polarized light), where H is the magnetic field and E is the electric field. The obtainment of H and E is well known. Specifically, the incident electric field E₀⁺ and the reflected electric field E₀⁻ at the interface between the DBR layer 116 and the ARC layer 104 can be expressed as in Equation 3. The DBR layer 116 is formed of alternately disposed third and fourth material layers 116a and 116b respectively having refraction indexes of n₃ and n₄ (n₄≠n₃).

$${E}_{0}^{+} = {e}^{- i {k}_{4} {d}_{4}} [ \frac{1}{2} i ( \frac{{ξ}_{4} {k}_{3}}{{ξ}_{3} {k}_{4}} - \frac{{ξ}_{3} {k}_{4}}{{ξ}_{4} {k}_{3}} ) sin ( {k}_{3} {d}_{3} ) ] \\ {E}_{0}^{-} = {e}^{i K ( λ ) A} - {e}^{i {k}_{4} {d}_{4}} \\ X [ cos ( {k}_{3} {d}_{3} ) + \frac{1}{2} i ( \frac{{ξ}_{4} {k}_{3}}{{ξ}_{3} {k}_{4}} - \frac{{ξ}_{3} {k}_{4}}{{ξ}_{4} {k}_{3}} ) sin ( {k}_{3} {d}_{3} ) ] \\ {k}_{i} = ( ω / e ) {n}_{i} cos {θ}_{i} \qquad Equation 3$$

Here, K is the wave vector proceeding through the entire DBR layer 116, k₃ and k₄ are respectively the z components of the wave vector passing through the third and fourth material layers 116a and 116b, ζ₃ and λ₄ are respectively the polarization parameters of the third and fourth material layers 116a and 116b, ω is the frequency of the pumping beam, c is the speed of light (in TE polarization, c=1, in TM polarization c=nᵢ² for i=3 and 4), and d₃ and d₄ are the thicknesses of the third and fourth material layers 116a and 116b in nanometers.

Also, the incident magnetic field H₀⁺ and the reflected magnetic field H0− at the interface between the DBR layer 116 and the first ARC layer 104 can be obtained using Maxwell's Equations based on the results of Equation 3. In this way, the optical admittance of the DBR layer 116 can be obtained.

For the reflectivity of a pumping beam at the interface between the DBR layer 116 and the first ARC layer 104 to be 0, η₀=C/B=Yₖ must be satisfied based on Equations 1, 2, and 3. Accordingly, d₁ and d2 can be determined with respect to the combination of the first and second material layers having refractive indexes of n₁ and n₂, respectively.

In an embodiment of the present invention, the first material layer 102 is a TiO₂ layer having a thickness of approximately 161 nm and the second material layer is a SiO₂ layer having a thickness of approximately 202 nm. The refractive indexes of TiO₂ and SiO₂ are 2.1 and 1.45, respectively.

In the above described embodiment of the present invention, the reflectivity of the interface between the DBR layer 116 and the ARC layer 104 is reduced to 5%, down from 30% in the conventional technology with respect to the pumping beam, and thus the transmission of the pumping beam is maximized and the pumping efficiency, that is, the percentage of the pumping beam incident on the gain region, can be improved from 70% to 95%. Accordingly, light output and lasing efficiency in the gain region can be significantly increased, and therefore, the light output of the VECSEL device can be increased.

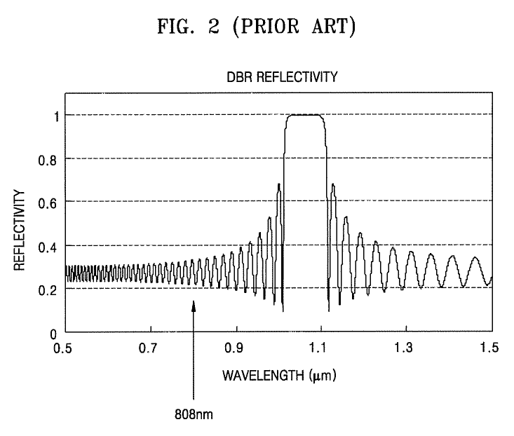

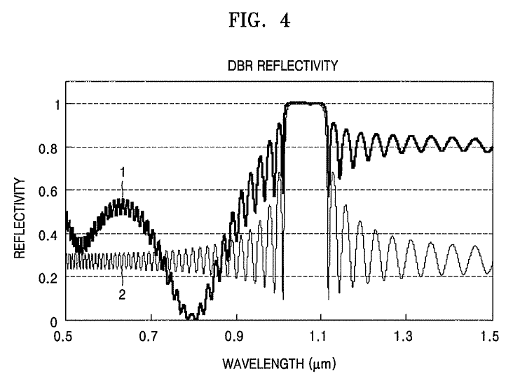

FIG. 4 is a graph of the reflectivity of the DBR layer 116 according to the wavelength of the pumping beam in the VECSEL device of FIG. 3 (Graph 1). The graph of FIG. 2 showing the reflectivity of the DBR of the conventional VECSEL device is also shown in FIG. 4 for comparison (Graph 2). When the first ARC layer is optimized according to the first embodiment illustrated in FIG. 3, the reflectivity at the interface of the DBR layer 116 is reduced to less than 2%.

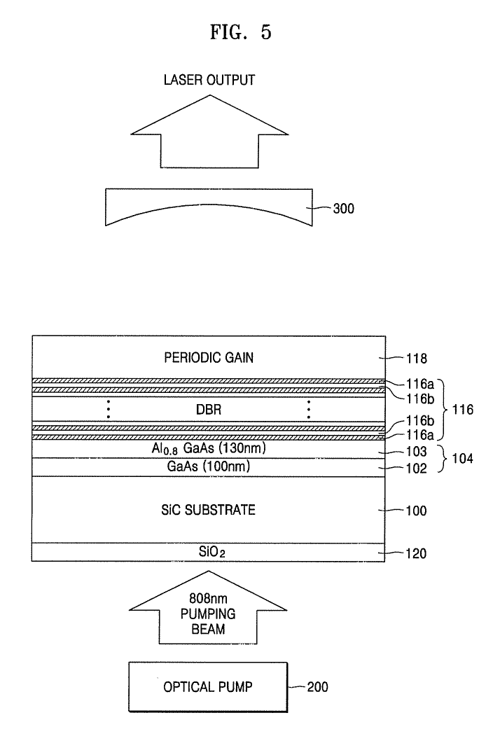

FIG. 5 is a schematic cross-sectional view of a VECSEL device according to another embodiment of the present invention. The description of the components common to the present and previous embodiments are not repeated.

Referring to FIG. 5, in the present embodiment, the first ARC layer 104 includes a GaAs layer 112 having a thickness of approximately 100 nm and an Al_{0.8}GaAs layer having a thickness of approximately 130 nm. A second ARC layer 120 composed of a second light-transmitting material is further included on a bottom surface of the transparent substrate 100 to reduce loss of the pumping beam. The second light-transmitting insulating material may be SiO₂ or TiO₂. The second ARC layer may have a thickness of ¼ of the pumping wavelength λ.

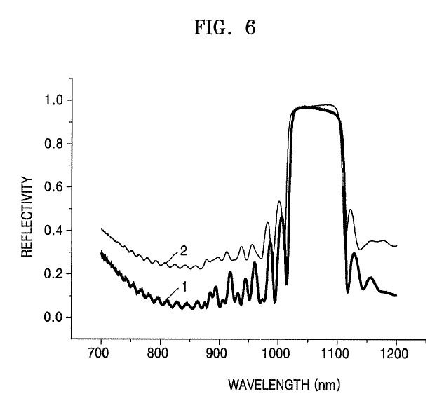

FIG. 6 is a graph of the reflectivity of the DBR layer 116 according to the wavelength of the pumping beam in the VECSEL device of FIG. 5 (Graph 1). The graph in FIG. 2 illustrating the reflectivity of the DBR layer of the conventional VECSEL device is shown for comparison. When the first ARC layer 104 is optimized as described in the previous embodiment, the reflectivity of the DBR layer 116 is reduced to less than 2%.

According to the present invention, the loss of the pumping beam and the pumping efficiency can be increased during the VECSEL driving. Specifically, when a pumping beam is incident in a VECSEL in the present invention, the reflectivity of the pumping beam at the interface between the DBR layer and the ARC layer is 5%, down from 30% in the prior technology, and thus the transmittance of the pumping beam is optimized and the pumping efficiency incident on the gain region can be increased from 70% to 95% or more. Accordingly, the light output and the lasing efficiency in the gain region can be increased, and thus the light output of the VECSEL device can be increased as well.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A vertical external cavity surface emitting laser (VECSEL) device comprising:
a transparent substrate;
an optical pump radiating a pumping beam onto a first surface of the transparent substrate;
a first anti-reflection coating (ARC) layer of a first light-transmitting insulating material on a second surface of the transparent substrate to reduce incident loss of the pumping beam;
a distributed Bragg reflector (DBR) layer located on the first ARC layer;
a periodic gain layer formed on the DBR layer; and
an external cavity mirror facing the periodic gain layer,
wherein the DBR layer is disposed between the first ARC layer and the periodic gain layer.

2. The VECSEL device of claim 1, wherein the first light-transmitting insulating material has a different refraction index than the DBR layer.

3. The VECSEL device of claim 2, wherein the first ARC layer has a single-layer.

4. The VECSEL device of claim 3, wherein the first ARC layer has a single-layer structure and has a thickness of ¼ of the wavelength of the pumping beam.

5. The VECSEL device of claim 1, wherein the first ARC layer has a double-layer structure comprising a first material layer having a refractive index n1 and a second material layer having a refractive index n2 (n2≠n1).

6. The VECSEL device of claim 5, wherein the first ARC layer has a thickness such that the reflectivity p of the interface between the DBR layer and the first ARC layer is 5% or less with respect to the pumping beam.

7. The VECSEL device of claim 6, wherein the reflectivity p of the interface between the DBR layer and the ARC layer satisfies
$$ρ = \frac{{η}_{0} - Y}{{η}_{0} + Y} = \frac{{η}_{0} - \frac{C}{B}}{{η}_{0} + \frac{C}{B}}$$
where η0 is the modified optical admittance of the incident medium, B is the magnitude of an electric field at the interface between the ARC layer and the DBR layer, C is the magnitude of a magnetic field at the interface between the ARC layer and the DBR layer, and Y is the optical admittance of the DBR layer.

8. The VECSEL device of claim 7, wherein B and C satisfy
$$[ \begin{matrix}B \\ C\end{matrix} ] = [ \begin{matrix}cos {δ}_{1} & \frac{( i sin {δ}_{1} )}{{η}_{1}} \\ i {η}_{1} sin {δ}_{1} & cos {δ}_{1}\end{matrix} ] [ \begin{matrix}cos {δ}_{2} & \frac{( i sin {δ}_{2} )}{{η}_{2}} \\ i {η}_{2} sin {δ}_{2} & cos {δ}_{2}\end{matrix} ] [ \begin{matrix}1 \\ {Y}_{k} ( λ )\end{matrix} ]$$
$${δ}_{i} = ( 2 π / λ ) {n}_{i} {d}_{i} cos {θ}_{i} ( i = 1 , 2 )$$
where δ is the optical phase thickness of the DBR layer or ARC layer, Yₖ is the optical admittance of the DBR layer, η₁ and η₂ are respectively the modified optical admittances of the first and second material layers, θᵢ is the incidence angle of the pumping beam, λ is the wavelength of the pumping beam, d₁ and d₂ are respectively the thicknesses of the first and second material layers, and n₁ and n₂ are respectively the refraction indexes of the first and second material layers.

9. The VECSEL device of claim 8, wherein the first ARC layer includes TiO₂ layers having a thickness of 161 nm and SiO₂ layers having a thickness of 202 nm stacked sequentially on the second surface of the transparent substrate.

10. The VECSEL device of claim 8, wherein the first ARC layer includes layers comprised of gallium and arsenide having a thickness of approximately 100 nm, and layers comprised of aluminum, gallium and arsenide having a thickness of approximately 130 nm stacked sequentially on the second surface of the transparent substrate.

11. The VECSEL device of claim 1, wherein the DBR layer includes AlAs layers and AlGaAs layers alternately stacked.

12. The VECSEL device of claim 1, wherein the transparent substrate is a SiC substrate.

13. The VECSEL device of claim 1, further comprising a second ARC layer made of a second light transmitting insulating material on the first surface of the transparent substrate to reduce the incident loss of the pumping beam.

14. The VECSEL device of claim 13, wherein the second light transmitting insulating material is SiO₂.

15. The VECSEL device of claim 14, wherein the second ARC layer has a thickness of ¼ of the wavelength of the pumping beam.

16. The VECSEL device of claim 1, wherein the wavelength of the pumping beam is in the range from approximately 700 nm to approximately 900 nm.

17. A vertical external cavity surface emitting laser (VECSEL) device comprising:
a transparent substrate having a first surface and a second surface;
an optical pump radiating a pumping beam onto the first surface of the transparent substrate;
a first anti-reflection coating (ARC) layer of a first light-transmitting insulating material on the second surface of the transparent substrate to reduce incident loss of the pumping beam;
a second ARC layer made of a second light transmitting insulating material on the first surface of the transparent substrate to reduce the incident loss of the pumping beam
a distributed Bragg reflector (DBR) layer located on the first ARC layer;
a periodic gain layer formed on the DBR layer; and
an external cavity mirror facing the periodic gain layer,
wherein the DBR layer is disposed between the first ARC layer and the periodic gain layer.

18. The VECSEL device of claim 2, wherein the first ARC layer has a double-layer wherein a first layer of the first ARC layer is TiO₂ and a second layer of the first ARC layer is SiO₂.

19. The VECSEL device of claim 1, wherein the transparent substrate is a diamond substrate.

20. The VECSEL device of claim 13, wherein the second light transmitting insulating material is TiO₂.
